(19) United States
(12) Patent Application Publication
(10) Pub. No.: US 2008/0274615 A1
(43) Pub. Date: Nov. 6, 2008

(54) Atomic Layer Deposition Methods, Methods of Forming Dielectric Materials, Methods of Forming Capacitors, And Methods of Forming DRAM Unit Cells

(76) Inventor: Brian A. Vaartstra, Nampa, ID (US)

Correspondence Address: WELLS ST. JOHN P.S., 601 W. FIRST AVENUE, SUITE 1300, SPOKANE, WA, 99201, US

(21) Appl. No.: 11/743,415

(22) Filed: May 2, 2007

(51) Int. Cl. H01L 21/44; H01L 21/20; H01L 21/8242

(52) U.S. Cl. 438/685; 438/255; 438/386; 438/681; 257/E21.09; 257/E21.476; 257/E21.646

(57) ABSTRACT

Some embodiments include methods of forming metal-containing oxides. The methods may utilize ALD where a substrate surface is exposed to an organometallic composition while the substrate surface is at a temperature of at least 275° C. to form a metal-containing layer. The metal-containing layer may then be exposed to at least one oxidizing agent to convert the metal-containing layer to a metal-containing oxide. The ALD may occur in a reaction chamber, with the oxidizing agent and the organometallic composition being present within such chamber at substantially non-overlapping times relative to one another. The oxidizing agent may be a milder oxidizing agent than ozone. The metal-containing oxide may be utilized as a capacitor dielectric, and may be incorporated into a DRAM unit cell.

### TECHNICAL FIELD

Atomic layer deposition methods, methods of forming dielectric materials, methods of forming capacitors, and methods of forming dynamic random access memory (DRAM) unit cells.

### BACKGROUND

Dielectric materials have many applications in integrated circuit fabrication. For instance, dielectric materials may be utilized in capacitor devices to separate a pair of capacitor electrodes from one another. As another example, dielectric materials may be utilized as tunnel dielectric in transistor devices to separate a conductive transistor gate from a channel region. As yet another example, dielectric materials may be utilized for electrically isolating adjacent circuit components from one another.

Numerous compositions have been developed which are suitable for utilization as dielectric materials in integrated circuit applications. Some compositions showing particular promise for utilization as capacitor dielectric and transistor tunnel dielectric are metal-containing oxides, such as hafnium oxide, zirconium oxide, tantalum oxide, titanium oxide and niobium oxide.

Difficulties are encountered in the formation of metal-containing oxides in that such oxides frequently contain impurities unless formed at high temperatures with aggressive oxidizers (such as ozone). Yet the aggressive oxidizers may problematically attack substrate structures during formation of the metal-containing oxides, and the high temperatures may problematically induce premature breakdown of precursors utilized for the formation of the metal-containing oxides. Accordingly, it is desired to develop new procedures for forming metal-containing oxides.

Numerous deposition methods may be utilized to form dielectric materials, including, for example, chemical vapor deposition (CVD), atomic layer deposition (ALD), physical vapor deposition (PVD), etc. Some embodiments described herein, while not limited to any particular deposition process except to the extent explicitly stated in the claims which follow, may be particularly useful for ALD technology.

ALD technology typically involves formation of successive atomic layers on a substrate. Such layers may comprise, for example, an epitaxial, polycrystalline, and/or amorphous material. ALD may also be referred to as atomic layer epitaxy, atomic layer processing, etc.

Described in summary, ALD includes exposing an initial substrate to a first chemical species to accomplish chemisorption of the species onto the substrate. Theoretically, the chemisorption forms a monolayer that is uniformly one atom or molecule thick on the entire exposed initial substrate. In other words, a saturated monolayer. Practically, as further described below, chemisorption might not occur on all portions of the substrate. Nevertheless, such an imperfect monolayer is still a monolayer in the context of this document. In many applications, merely a substantially saturated monolayer may be suitable. A substantially saturated monolayer is one that will still yield a deposited layer exhibiting the quality and/or properties desired for such layer.

The first species is purged from over the substrate and a second chemical species is provided to chemisorb onto or react with the first monolayer of the first species. Any unreacted second species is then purged and the step repeated with the exposure of the second species monolayer to the first species. In some cases, the two monolayers may be of the same species. Also, a third species or more may be successfully chemisorbed and purged just as described with first and second species. It is noted that one or more of the first, second and third species may be mixed with inert gas to speed up pressure saturation within a reaction chamber.

Purging may involve a variety of techniques including, but not limited to, contacting the substrate and/or monolayer with a carrier gas and/or lowering pressure to below the deposition pressure to reduce the concentration of a species contacting the substrate and/or chemisorbed species. Examples of carrier gases include N₂, Ar, He, Ne, Kr, Xe, etc. Purging may instead include contacting the substrate and/or monolayer with any substance that allows chemisorption by-products to desorb and reduces the concentration of a species preparatory to introducing another species.

ALD is often described as a self-limiting process in that a finite number of sites exist on a substrate to which the first species may form chemical bonds. The second species might only bond to the first species and thus may also be self-limiting. Once all of the finite number of sites on the substrate are bonded with a first species, the first species will often not bond to other of the first species already bonded with the substrate. However, process conditions may be varied in ALD to promote such bonding and render ALD not self-limiting. Accordingly, ALD may also encompass a species forming other than one monolayer at a time by stacking of a species.

The general technology of chemical vapor deposition (CVD) includes a variety of more specific processes, including, but not limited to, plasma-enhanced CVD and others. CVD is commonly used to form non-selectively a complete, deposited material on a substrate. One characteristic of CVD is the simultaneous presence of multiple species in the deposition chamber that react to form the deposited material.

Under most CVD conditions, deposition occurs largely independent of the composition of surface properties of an underlying substrate. By contrast, chemisorption rate in ALD might be influenced by the composition, crystalline structure, and other properties of a substrate or chemisorbed species. Other process conditions, for example, pressure and temperature, may also influence chemisorption rate.

### BRIEF DESCRIPTION OF THE DRAWINGS

FIGS. 1-3 are diagrammatic cross-sectional views of a portion of a semiconductor construction at processing stages of an embodiment.

FIG. 4 is a diagrammatic cross-sectional view of a reaction chamber that may be utilized in some embodiments.

FIGS. 5-9 are diagrammatic cross-sectional views of a portion of a semiconductor construction at processing stages of an embodiment.

### DETAILED DESCRIPTION OF THE ILLUSTRATED EMBODIMENTS

Some embodiments include methods for atomic layer deposition (ALD) of metal-containing oxides. The metal-containing oxides may be oxides of hafnium, zirconium, niobium, tantalum or titanium.

Conventional methods for forming such oxides may use precursors that undergo thermal decomposition at substrate temperatures above 225° C. For instance, conventional precursors utilized for ALD of hafnium oxide and zirconium oxide are tetrakis(dimethylamino)hafnium (TDMAH) and tetrakis(ethylmethylamino)zirconium (TEMAZ), respectively. Thermal degradation of such precursors during an ALD process may cause a chemical vapor deposition (CVD) component to be present in the ALD process, which may lead to poor step coverage.

Some embodiments utilize metal-containing precursors having high thermal stability in combination with oxidizing agents less aggressive than ozone during ALD of metal-containing oxides. The oxides may be formed with high purity, and good step coverage.

In some embodiments, two or more precursors may be flowed into a reaction chamber to form a metal-containing oxide over at least a portion of a substrate. One of the precursors is an organometallic material, and the other is an oxidant. The precursors may be within the reaction chamber at different and substantially non-overlapping times relative to one another. Specifically, substantially all of one precursor may be removed from within the reaction chamber prior to introducing the other precursor into the reaction chamber. The term “substantially all” is utilized to indicate that an amount of precursor within the reaction chamber is reduced to a level where gas phase reactions with subsequent precursors (or reactant gases) do not degrade the properties of a material deposited on the substrate. In some embodiments, such may indicate that all of a first precursor is removed from the reaction chamber prior to introducing a second precursor. In some embodiments, such may indicate that at least all measurable amounts of the first precursor are removed from the reaction chamber prior to introducing the second precursor into the chamber.

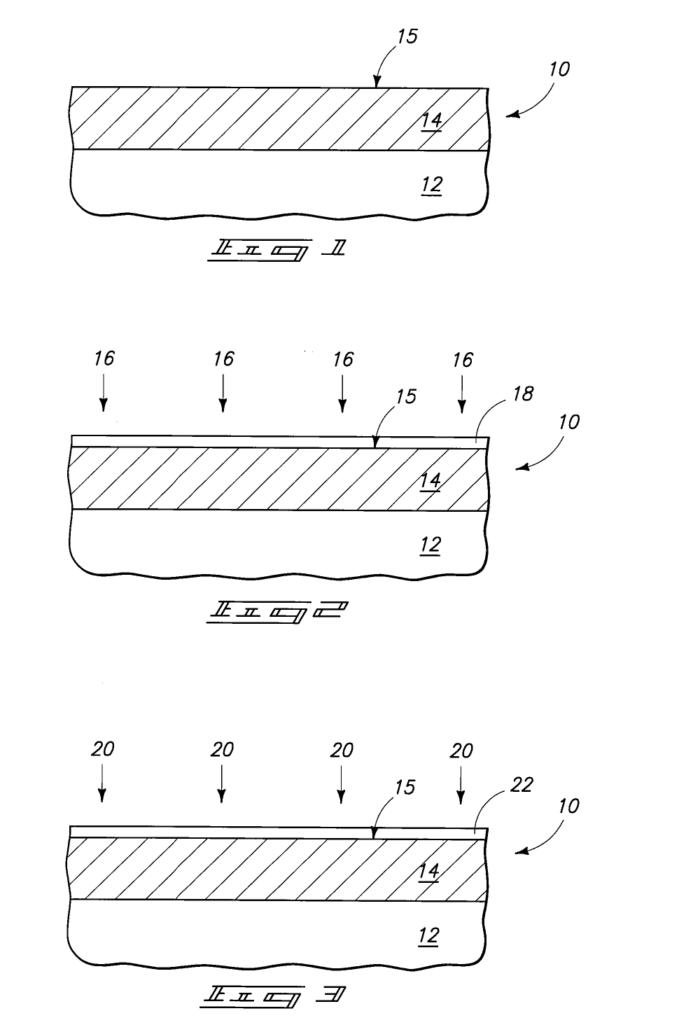

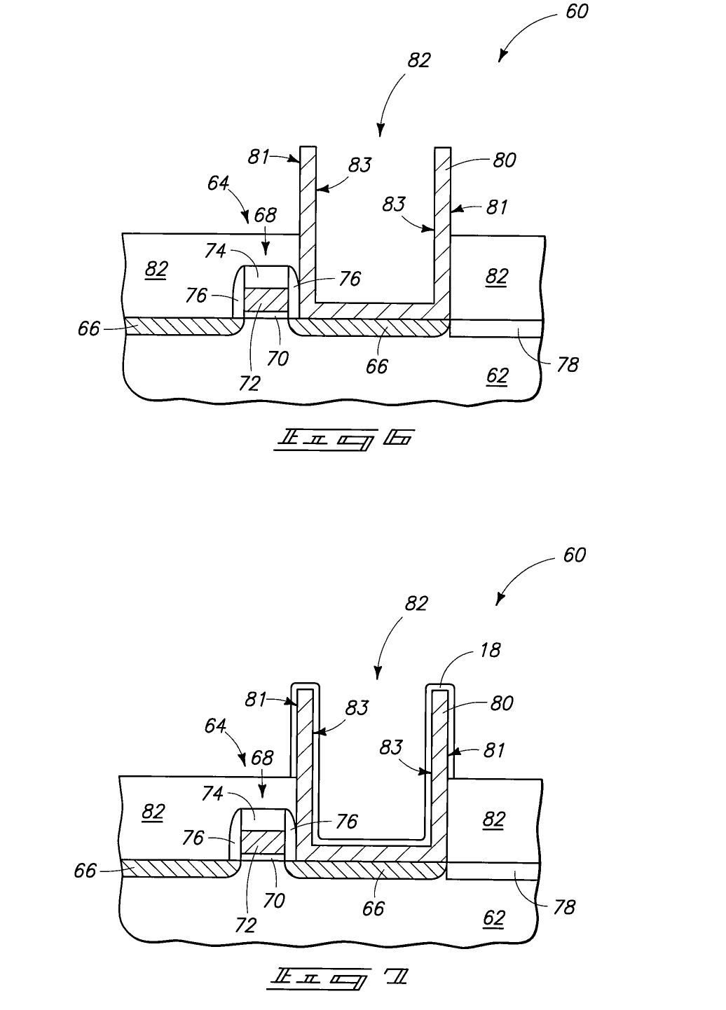

Example embodiments are described with reference to FIGS. 1-9. FIGS. 1-3 illustrate a first process, FIGS. 5-9 illustrate a second process, and FIG. 4 illustrates a reaction chamber that may be utilized in either of the first and second processes.

Referring to FIG. 1, a portion of a semiconductor construction 10 is illustrated. The construction comprises a base 12. The base may, for example, comprise, consist essentially of, or consist of monocrystalline silicon, and may be a portion of a monocrystalline silicon wafer. The base may be referred to as a semiconductor substrate. The terms “semiconductive substrate,” “semiconductor construction” and “semiconductor substrate” mean any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductive substrates described above.

Although base 12 is shown to be homogenous, the base may comprise numerous layers in some embodiments. For instance, base 12 may correspond to a semiconductor substrate containing one or more layers associated with integrated circuit fabrication. Such layers may correspond to one or more of metal interconnect layers, barrier layers, insulator layers, etc.

A conductive material 14 is over base 12. The conductive material may comprise anything that a metal-containing oxide would be formed over, and may, for example, comprise, consist essentially of, or consist of one or more of various metals (for instance, tungsten, titanium, copper, etc.), metal-containing compositions (for instance, metal nitride, metal silicides, etc.) and conductively-doped semiconductor materials (for instance, conductively-doped silicon, conductively-doped germanium, etc.). In some embodiments, conductive material 14 may be omitted and a metal-containing oxide formed directly against base 12. In some embodiments, the metal-containing oxide may be formed on an insulative material.

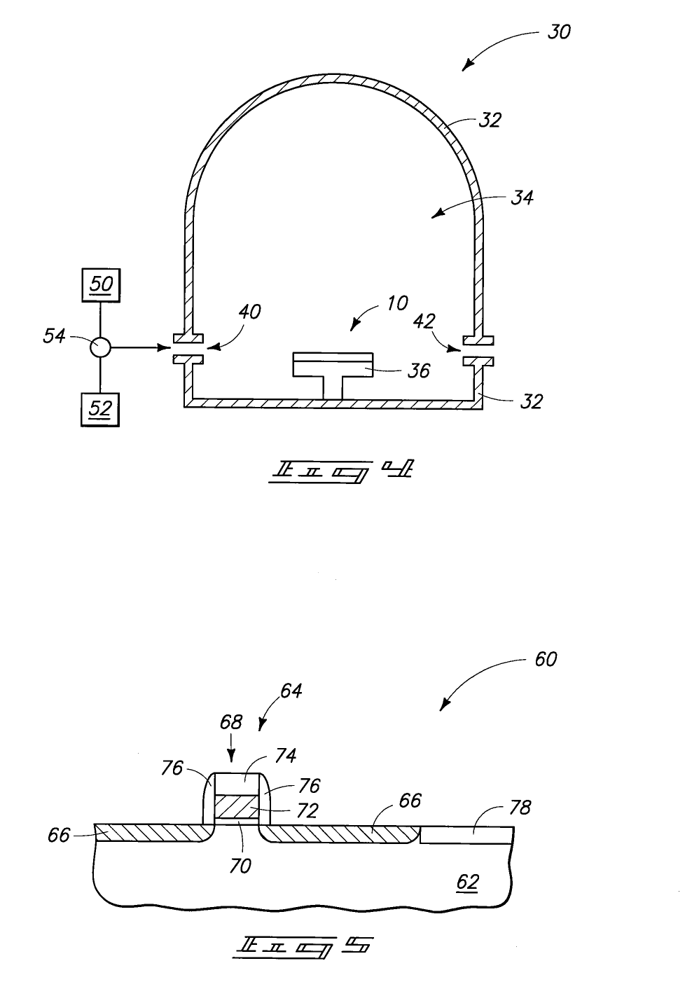

Conductive material 14 comprises an exposed surface 15. Such exposed surface may be considered an exposed surface of a semiconductor substrate in some embodiments. Surface 15 may be treated with an ALD process to form a metal-containing oxide over such surface, as discussed with reference to FIGS. 2 and 3. Specifically, FIG. 2 shows a first stage of the ALD process where the surface is treated with a first reactant to form a layer on the surface, and FIG. 3 shows a second stage of the ALD process where the layer is converted to an oxide.

Referring to FIG. 2, surface 15 is exposed to a metal-containing reactant 16 to form a metal-containing layer 18 over the surface. The layer 18 results from reaction of reactant 16 with exposed surface 15.

In some embodiments, the reactant 16 comprises an organometallic composition stable to temperatures of at least 275° C. Thus, surface 15 may be at a temperature of at least 275° C. during exposure to reactant 16, and yet there will be substantially no thermal decomposition of reactant 16. The reactant may thus be utilized at relatively high temperatures to achieve the advantages of such high temperatures (notably, enhanced purity of layer 18 relative to a purity which would be achieved at lower temperatures), without the problems of having thermal breakdown products interfering with the deposition process. The problems associated with thermal breakdown products may include CVD type reactions that may interfere with the ALD process.

The enhanced purity achieved at higher temperatures may be due to more efficient bond cleavage, and/or to more efficient removal of reaction byproducts (for instance, carbon-containing byproducts) than is achieved at lower temperatures.

The term “substantially no thermal decomposition” refers to processes in which the amount of thermal decomposition is below a threshold which will interfere with an ALD process to create an amount of impurity that exceeds desired tolerances. In some embodiments, there will be no detectable impurity in layer 18, and in some embodiments there will be no detectable thermal decomposition of reactant 16 during exposure to the temperature in excess of 275° C.

The organometallic reactant 16 may comprise any metal desired to be converted to a metal-containing oxide, and in some embodiments may comprise hafnium (Hf), zirconium (Zr), niobium (Nb), tantalum (Ta) or titanium (Ti). The organic component of the organometallic reactant may comprise multiple hydrocarbyl groups. The term “hydrocarbyl group” means a group comprising at least carbon and hydrogen. The hydrocarbyl groups may optionally comprise one or more substituents and/or hetero atoms. Example substituents include halo, alkoxy, nitro, hydroxy, carboxyl, epoxy, acrylic, etc. Example hetero atoms include halogens, sulfur, nitrogen and oxygen. A hydrocarbyl group may include a cyclic group, or may be a cyclic group. In some embodiments, at least one of the hydrocarbyl groups comprises a pentadienyl group coordinated to the metal of reactant 16. The pentadienyl group may be a cyclopentadienyl group, and in some embodiments may be comprised by a methyl cyclopentadienyl group.

In some embodiments, reactant 16 will comprise at least four hydrocarbyl groups coordinated to a metal. Each of the four hydrocarbyl groups may comprise from 1 to 10 carbon atoms. An example reactant comprising hafnium and four hydrocarbyl groups is shown below as Formula I.

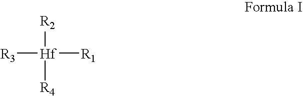

In Formula I, R₁, R₂, R₃ and R₄ are carbon-containing groups, and in some embodiments each may contain from 1-10 carbon atoms.

The compound shown above as Formula I may correspond to, for example, Formula II.

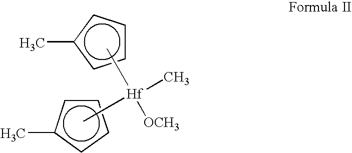

In Formula II, four hydrocarbyl groups are coordinated to hafnium. Two of the four hydrocarbyl groups include cyclopentadienyl groups, one of the four hydrocarbyl groups is a methyl group, and one of the four hydrocarbyl groups is a methoxy group. The coordination from the hafnium to the cyclopentadienyl groups is shown extending to the electron density of the conjugated double bonds rather than to particular atoms.

An example of a reactant 16 comprising zirconium is shown below as Formula III.

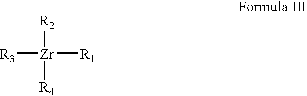

In Formula III, R₁, R₂, R₃ and R₄ are carbon-containing groups, and in some embodiments each may contain from 1-10 carbon atoms.

The compound shown above as Formula III may correspond to, for example, Formula IV.

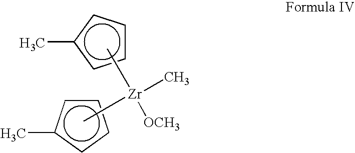

In Formula IV, four hydrocarbyl groups are coordinated to zirconium. Two of the four hydrocarbyl groups include cyclopentadienyl groups, one of the four hydrocarbyl groups is a methyl group, and one of the four hydrocarbyl groups is a methoxy group. The coordination from the hafnium to the cyclopentadienyl groups is shown extending to the electron density of the conjugated double bonds rather than to particular atoms.

Referring next to FIG. 3, the metal-containing layer 18 (FIG. 2) is exposed to at least one oxidizing agent 20 to convert the layer 18 to a metal oxide-containing layer 22. The oxidizing agent 20 may be a milder oxidizing agent than ozone. An oxidizing agent is milder than the ozone if it has a lower reduction potential than ozone. In some embodiments, the at least one oxidizing agent will consist of one or more compositions selected from the group consisting of water, O₂, nitrous oxide, nitric oxide, sulfite, sulfate, alcohols and ketones.

The utilization of a mild oxidizing agent may reduce undesired attack of the oxidizing agent on various surfaces of construction 10 that may be exposed to the oxidizing agent. For instance, layer 18 (FIG. 3) may be initially very thin, so that some of material 14 is exposed through layer 18 during the oxidation of layer 18. The weak oxidizing agent 20 is less likely to detrimentally affect layer 14 than would a stronger oxidizing agent, like ozone.

The oxidation of layer 18 to convert the layer to oxide 22 may be conducted at about the same temperature as the formation of layer 18 (in other words, within about 25° C. of the temperature of formation of layer 18), or may be conducted at a much different temperature than that utilized for formation of layer 18. In some embodiments, the oxidation of layer 18 may be conducted at a temperature that is at least about 25° C. greater than the temperature of formation of layer 18. For instance, layer 18 may be formed while surface 15 is at a temperature of about 275° C., and the oxidation of layer 18 may be conducted while the layer is maintained at a temperature of at least about 300° C., at least about 350° C., or even at least about 400° C.

The utilization of the high temperatures for the oxidation may reduce contamination within metal oxide-containing layer 22. For instance, the high temperatures of the oxidation may enhance removal of carbon from the metal oxide-containing layer. The high temperature oxidation may be achieved without detriment to conductive material 14 through utilization of relatively weak oxidizing agents.

If the oxidation of layer 18 is conducted at a higher temperature than the initial formation of layer 18, there may be a heating step between the formation of the layer and the oxidation of the layer. Specifically, the metal-containing layer may be formed at a first temperature, heated to a second temperature higher than the first temperature, and then converted to oxide while it is maintained at the second temperature.

The formation of layer 22 may be considered to occur through an ALD process where a first layer 18 is formed with a first precursor 16, and subsequently the first layer is converted to an oxide 22. Such may form the oxide 22 to be about one monolayer thick. In subsequent processing, an upper surface of oxide 22 may be exposed to the first precursor to form a metal-containing layer over such upper surface, and the metal-containing layer may then be oxidized to form another layer of oxide over oxide 22. This process may be repeated to form a desired thickness of oxide over material 14.

The ALD processing may be conducted in a reaction chamber, such as described with reference to an apparatus 30 in FIG. 4.

Apparatus 30 includes a vessel 32 having a reaction chamber 34 therein. A substrate holder 36 is provided within the reaction chamber 34, and such supports a substrate 10.

An inlet 40 extends through a sidewall of vessel 32 and into reaction chamber 34, and an outlet 42 extends through a sidewall of vessel 32 and from reaction chamber 34. In operation, reactants (i.e., precursors) are introduced into inlet 40 and flowed into reaction chamber 34, and materials are purged or otherwise exhausted from chamber 34 thorough outlet 42.

Valves (not shown) may be provided across the inlet and outlet to control flow of materials into and out of the chamber. Additionally, a pump (not shown) may be provided downstream from outlet 42 to assist in exhausting materials from the reaction chamber.

Apparatus 30 is configured for flow of a pair of precursors into reaction chamber 34. Specifically, a pair of sources 50 and 52 comprising first and second reactant materials, respectively, are shown upstream of inlet 40. The sources are in fluid communication with a valve 54 so that material may be flowed from the sources, through valve 54, and then into inlet 40. Valve 54 may be configured so that only one precursor at a time may be flowed from sources 50 and 52 into chamber 34. In other words, valve 54 may be configured so that precursor flow from source 50 into reaction chamber 34 is exclusive relative to precursor flow from source 52, and vice versa. Accordingly, precursor flow from source 50 will be at a different time than precursor flow from source 52. Further, if reaction chamber 34 is purged between the time that precursor is flowed from source 50 into the chamber and the time that precursor is flowed from source 52 into the chamber, the precursors from sources 50 and 52 will not mix within chamber 34. In such applications, precursor flow from sources 50 and 52 into chamber 34 will be at different and substantially non-overlapping times relative to one another, and typically will be at different and absolutely non-overlapping times relative to one another. Apparatus 30 may thus be utilized for ALD processes.

The apparatus 30 is shown schematically, and in other embodiments other configurations may be utilized for ALD processes to accomplish non-overlapping flow of two or more precursors into a reaction chamber. Also, additional materials may be flowed into the reaction chamber besides the precursors from sources 50 and 52. For instance, an inert gas may be flowed into the reaction chamber either with precursor to assist in flowing the precursor into the reaction chamber, or after the flow of precursor to assist in purging the precursor from the reaction chamber.

The processing described above with reference to FIGS. 1-4 may be utilized for forming metal oxide dielectric for numerous integrated circuit components. For instance, the metal oxide dielectric may be utilized as tunnel oxide of transistors, as capacitor dielectric, and/or as electrical isolation between adjacent circuit components.

FIGS. 5-9 illustrate an embodiment in which metal oxide is formed as capacitor dielectric of a DRAM unit cell.

Referring to FIG. 5, a semiconductor construction 60 is illustrated. The construction comprises a semiconductor base 62 which may comprise, consist essentially of, or consist of monocrystalline silicon.

A transistor 64 is supported by the base. The transistor comprises a pair of source/drain regions 66 extending into the base as conductively-doped diffusion regions, and comprises a gate stack 68 over base 62 and between the source/drain regions. The gate stack comprises tunnel dielectric 70, electrically conductive gate material 72 and an electrically insulative capping layer 74.

The tunnel dielectric 70 may comprise any suitable composition or combination of compositions, and may, for example, comprise, consist essentially of, or consist of silicon dioxide and/or one or more metal oxides. If the tunnel dielectric comprises metal oxide, such may be formed utilizing the processing of FIGS. 1-4.

The conductive gate material 72 may comprise any suitable composition or combination of compositions, and may, for example, comprise, consist essentially of, or consist of one or more of various metals, metal-containing compounds, and conductively-doped semiconductor materials.

Electrically insulative capping layer 74 may comprise any suitable composition or combination of compositions, and may, for example, comprise, consist essentially of, or consist of one or more of silicon dioxide, silicon nitride and silicon oxynitride.

A pair of electrically insulative sidewall spacers 76 are along sidewalls of the gate stack 68. The sidewall spacers may comprise any suitable composition or combination of compositions, and may, for example, comprise, consist essentially of, or consist of one or more of silicon dioxide, silicon nitride and silicon oxynitride.

The gate stack 68 may be part of a wordline that extends into and out of the plane of the cross-section of FIG. 5.

An isolation region 78 extends within base 62 adjacent one of the source/drain regions 66. The isolation region electrically isolates transistor 64 from other circuitry (not shown) adjacent the transistor. The isolation region may comprise any suitable electrically insulative composition or combination of electrically insulative compositions. In some embodiments, the isolation region may comprise, consist essentially of, or consist of one or more of silicon oxide, silicon nitride, silicon oxynitride, and various metal oxides. If the isolation region comprises metal oxides, such may be formed utilizing the processing described above with reference to FIGS. 1-4.

Referring to FIG. 6, a capacitor storage node 80 is formed over one of the source/drain regions, and electrically coupled to such source/drain region. The capacitor storage node is shown formed as a container having an opening 82 extending therein. The container has an interior surface 83 within the opening, and exterior surface 81 surrounding the opening.

An electrically insulative material 82 extends over base 62. The capacitor storage node 80 is within an opening in the insulative material 82.

The container-shaped capacitor storage node may be formed utilizing conventional processing which may include formation of dielectric material 82 to a first thickness that is at least to the height of the uppermost portion of storage node 80, deposition of the material of the storage node within an opening in the insulative material, etching of the material of storage node 80 from over the insulative material, and reduction of a height of the insulative material to the shown height. The patterning for locations of openings may be conducted utilizing photoresist masks (not shown).

Capacitor storage node 80 may comprise any suitable composition or combination of compositions, and may, for example, comprise, consist essentially of, or consist of any of various metals, metal-containing compounds and conductively-doped semiconductor materials. The storage node is shown to be homogeneous, but may comprise multiple discrete layers in other embodiments. The storage node may contact the conductively-doped source/drain region through a metal silicide interface (not shown). In some embodiments, the surfaces 81 and 83 will comprise, consist essentially of, or consist of metal nitride, such as, for example, titanium nitride. In such embodiments, storage node 80 may consist of metal nitride, or may comprise a metal nitride layer over one or more other conductive materials.

Insulative material 82 may comprise any suitable composition or combination of compositions and may, for example, comprise one or more of silicon dioxide and various doped silicate glasses (such as, for example, borophosphosilicate glass (BPSG)).

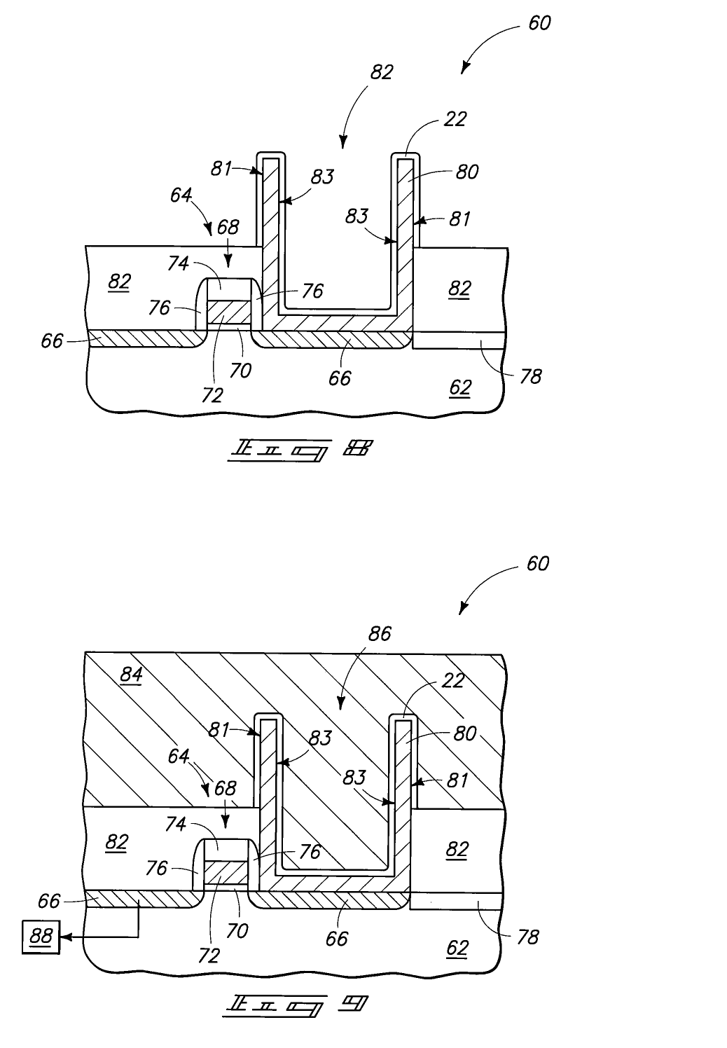

Referring to FIG. 7, a metal-containing layer 18 of the type described above with reference to FIG. 2 is formed along surfaces 81 and 83 utilizing the processing discussed above. The metal-containing layer may comprise hafnium, zirconium, niobium, tantalum or titanium.

Referring to FIG. 8, layer 18 (FIG. 7) is converted to metal oxide 22 utilizing processing of the type discussed above with reference to FIG. 3. The metal oxide may comprise, consist essentially of, or consist of hafnium oxide, zirconium oxide, niobium oxide, tantalum oxide or titanium oxide.

The processing of FIGS. 7 and 8 may be repeated multiple times to form a capacitor dielectric material of desired thickness and composition. The metal used from one iteration to another may vary so that the capacitor dielectric comprises a mixture of metal oxides. Such mixture may comprise, consist essentially of, or consist of various combinations of hafnium oxide, zirconium oxide, niobium oxide, tantalum oxide and titanium oxide. Alternatively, the same metal may be used from one iteration to another so that the entirety of the dielectric consists of hafnium oxide, zirconium oxide, niobium oxide, tantalum oxide or titanium oxide.

Referring to FIG. 9, a capacitor plate 84 is formed over dielectric 22. The capacitor plate may comprise any suitable electrically conductive composition or combination of compositions, and may, for example, comprise, consist essentially of, or consist of one or more of various metals, metal-containing compounds, and conductively-doped semiconductor materials.

The capacitor plate 84, storage node 80 and dielectric 22 together form a capacitor 86. Such capacitor is in ohmic connection with one of the source/drain regions 66. The other of the source/drain regions may be electrically coupled to a bitline 88. Such coupling may occur before or after fabrication of the storage node 80.

The transistor 64 and capacitor 86 together form a DRAM unit cell. Such unit cell may be part of a DRAM array comprising a plurality of substantially identical unit cells fabricated simultaneously with one another.

The DRAM array may be incorporated into electronic system, such as, for example, a clock, television, cell phone, personal computer, automobile, industrial control system, aircraft, etc.

### EXAMPLES

### Example 1, Method of Forming Hafnium Oxide Using Formula II ((^{Me}Cp)₂Hf(OMe)(Me))

1) (^{Me}Cp)₂Hf(OMe)(Me) is heated to 80° C. and the vapor above the compound is flowed into a reaction chamber using 25 standard cubic centimeters per minute (sccm) helium carrier gas; a substrate within the chamber has a surface heated to about 275° C.;

2) the chamber is pumped down for 15 seconds with a 200 sccm N₂ purge;

3) the N₂ purge is increased to 1200 sccm for 15 seconds, this may increase pressure in the chamber and thus increase temperature;

4) oxidizing agent (for instance, O₂ or water) is provided either by itself or in a carrier gas, and the gas is flowed into the chamber at 1 liter/minute for 20 seconds;

5) an N₂ purge is conducted at 1200 sccm for 25 seconds;

6) the chamber is subjected to pumping without purge gas which reduces pressure in the chamber, and thus quickly reduces temperature, the pumping is conducted for 13 seconds; and

7) the chamber is pumped down for 2 seconds with a 200 sccm N₂ purge.

Steps 1-7 may be considered an iteration of an ALD process, and such iteration may be repeated multiple times to form the hafnium oxide to a desired thickness.

### Example 2, Method of Forming Zirconium Oxide Using Formula IV ((^{Me}Cp)₂Zr(OMe)(Me))

1) (^{Me}Cp)₂Zr(OMe)(Me) is heated to 90° C. and the vapor above the compound is flowed into a reaction chamber using 25 sccm helium carrier gas; a substrate within the chamber has a surface heated to about 275° C.;

2) the chamber is pumped down for 15 seconds with a 200 sccm N₂ purge;

3) the N₂ purge is increased to 1200 sccm for 15 seconds, this may increase pressure in the chamber and thus increase temperature;

4) oxidizing agent (for instance, O₂ or water) is provided either by itself or in a carrier gas, and the gas is flowed into the chamber at 1 liter/minute for 20 seconds;

5) an N₂ purge is conducted at 1200 sccm for 25 seconds;

6) the chamber is subjected to pumping without purge gas which reduces pressure in the chamber, and thus quickly reduces temperature, the pumping is conducted for 13 seconds; and

7) the chamber is pumped down for 2 seconds with a 200 sccm N₂ purge.

Steps 1-7 may be repeated multiple times to form the zirconium oxide to a desired thickness.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. An atomic layer deposition method, comprising:
exposing a substrate surface to an organometallic composition while the substrate surface is at a temperature of at least 275° C., the organometallic composition reacting with the substrate surface to form a metal-containing layer over said surface, the organometallic composition undergoing substantially no thermal decomposition while exposed to the temperature of at least 275° C.; and
exposing the metal-containing layer to at least one oxidizing agent to convert the metal-containing layer to a metal-containing oxide, the at least one oxidizing agent being a milder oxidizing agent than ozone.

2. The method of claim 1 wherein the exposure to the organometallic composition occurs while the substrate surface is at a first temperature, wherein the exposure to the oxidizing agent occurs while the metal-containing layer is at a second temperature, and wherein the second temperature is within about 25° C. of the first temperature.

3. The method of claim 1 wherein the exposure to the organometallic composition occurs while the substrate surface is at a first temperature, wherein the exposure to the oxidizing agent occurs while the metal-containing layer is at a second temperature, and wherein the second temperature is at least about 25° C. greater than the first temperature.

4. The method of claim 1 further comprising increasing a temperature of the metal-containing layer to above 275° C., and wherein the exposure to the oxidizing agent occurs while the temperature of the metal-containing layer is above 275° C.

5. The method of claim 4 wherein the temperature above 275° C. is a temperature of at least about 300° C.

6. The method of claim 4 wherein the temperature above 275° C. is a temperature of at least about 350° C.

7. The method of claim 4 wherein the temperature above 275° C. is a temperature of at least about 400° C.

8. The method of claim 1 wherein the at least one oxidizing agent consists of one or more compositions selected from the group consisting of water, O₂, nitrous oxide, nitric oxide, sulfite, sulfate, alcohols and ketones.

9. The method of claim 1 wherein the organometallic composition comprises at least one pentadienyl group coordinated to the metal.

10. The method of claim 1 wherein the organometallic composition comprises at least one cyclopentadienyl group coordinated to the metal.

11. The method of claim 1 wherein the organometallic composition comprises at least one methyl cyclopentadienyl group coordinated to the metal.

12. The method of claim 1 wherein the organometallic composition comprises four hydrocarbyl groups coordinated to the metal, and wherein each of the four hydrocarbyl groups comprises from 1 to 10 carbon atoms.

13. The method of claim 12 wherein two of the four hydrocarbyl groups include cyclopentadienyl groups, one of the four hydrocarbyl groups is a methyl group, and one of the four hydrocarbyl groups is a methoxy group.

14. The method of claim 1 wherein the metal-containing layer comprises Hf.

15. The method of claim 1 wherein the metal-containing layer comprises Zr.

16. The method of claim 1 wherein the metal-containing layer comprises Nb.

17. The method of claim 1 wherein the metal-containing layer comprises Ta.

18. The method of claim 1 wherein the metal-containing layer comprises Ti.

19. A method of forming a dielectric material, comprising:
forming a first layer over a substrate surface using a first precursor, the first precursor comprising an organometallic compound containing Hf, Zr, Nb, Ta or Ti; the substrate surface being at a temperature of at least 275° C. during the forming of the first layer;
heating the first layer to a second temperature above that utilized during formation of the first layer; and
while the first layer is at the second temperature, using a second precursor to convert the first layer to an oxide.

20. The method of claim 19 wherein the second temperature is at least about 300° C.

21. The method of claim 19 wherein the first precursor comprises Hf.

22. The method of claim 19 wherein the first precursor comprises Zr.

23. The method of claim 19 wherein the first precursor comprises Nb.

24. The method of claim 19 wherein the first precursor comprises Ta.

25. The method of claim 19 wherein the first precursor comprises Ti.

26. The method of claim 19 wherein the second precursor is a milder oxidizing agent than ozone.

27. The method of claim 26 wherein the milder oxidizing agent than ozone comprises a composition selected from the group consisting of water, O₂, nitrous oxide, nitric oxide, sulfite, sulfate, alcohols and ketones.

28. The method of claim 19 wherein the first precursor has the formula: 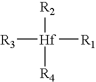
where R₁, R₂, R₃ and R₄ are carbon-containing groups.

29. The method of claim 19 wherein the first precursor has the formula:

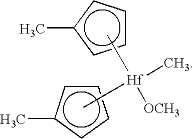

30. The method of claim 19 wherein the first precursor has the formula: 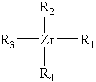
where R₁, R₂, R₃ and R₄ are carbon-containing groups.

31. The method of claim 19 wherein the first precursor has the formula:

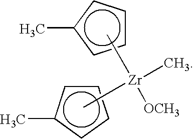

32. A method of forming a dielectric material, comprising:
placing a substrate within a reaction chamber;
flowing a metal-containing first precursor into the chamber and forming a layer over the substrate comprising metal from the metal-containing first precursor;
flowing a second precursor into the chamber, the first and second precursors being within the chamber at substantially non-overlapping times, the second precursor being an oxidizing agent weaker than ozone; and
using the second precursor to convert the layer to an oxide, the conversion to the oxide being conducted while the layer is at a temperature of at least 275° C.

33-39. (canceled)

40. A method of forming a capacitor, comprising:
forming an upwardly opening container over a semiconductor substrate, the container having an electrically conductive interior surface;
exposing the interior surface to a precursor comprising an organometallic composition, the exposing to the precursor occurring while the interior surface is at a temperature of at least 275° C., the precursor reacting with the interior surface to form a metal-containing layer over said surface;
exposing the metal-containing layer to at least one oxidizing agent to convert the metal-containing layer to a metal-containing oxide, the at least one oxidizing agent being a milder oxidizing agent than ozone;
the exposing to the precursor and the exposing to the oxidizing agent both occurring in a reaction chamber, the precursor and oxidizing agent being in the chamber at substantially non-overlapping times; and
forming an electrically conductive capacitor plate over the metal-containing oxide.

41-45. (canceled)

46. A method of forming a DRAM unit cell, comprising:
forming a transistor over a semiconductor substrate, the transistor comprising a pair of source/drain regions proximate a transistor gate;
forming a capacitor having a storage node in ohmic connection with one of the source/drain regions, the forming the capacitor comprising:
forming the storage node to be an upwardly opening container over the semiconductor substrate, the container having an electrically conductive interior surface;
exposing the interior surface to a precursor comprising an organometallic composition, the exposing to the precursor occurring while the interior surface is at a temperature of at least 275° C., the precursor reacting with the interior surface to form a metal-containing layer over said surface;
exposing the metal-containing layer to at least one oxidizing agent to convert the metal-containing layer to a metal-containing oxide, the at least one oxidizing agent being a milder oxidizing agent than ozone;
the exposing to the precursor and the exposing to the oxidizing agent both occurring in a reaction chamber, the precursor and oxidizing agent being in the chamber at substantially non-overlapping times; and
forming an electrically conductive capacitor plate over the metal-containing oxide.

47-51. (canceled)
